(19) United States
(12) Patent Application Publication
(10) Pub. No.: US 2011/0031119 A1
(43) Pub. Date: Feb. 10, 2011

(54) PLASTIC POTENTIOMETRIC ION-SELECTIVE SENSOR AND FABRICATION THEREOF

(75) Inventors: Hsiung Hsiao, Hsinchu City (TW); KuoTong Ma, Taichung City (TW); Li Te Yin, Tainan County (TW); Shen Kan Hsiung, Taoyuan County (TW)

Correspondence Address: LanWay IPR Services, P.O. Box 220746, Chantilly, VA, 20153, US

(73) Assignee: MIDDLELAND SENSING TECHNOLOGY INC., Hsinchu County (TW)

(21) Appl. No.: 12/536,578

(22) Filed: Aug. 6, 2009

(51) Int. Cl. G01N 27/26; B05D 5/12; C23C 14/34

(52) U.S. Cl. 204/416; 427/125; 204/192.17; 427/123

(57) ABSTRACT

The present invention discloses a plastic potentiometric ion-selective sensor based on field-effect transistors which can be fabricated to form the miniaturized component via sputtering and/or printing method. A plastic potentiometric ion-selective sensor doesn't need an additional bias voltage to convert the signals. The disclosed plastic sensor comprises a plastic substrate, at least one working electrode formed on the plastic substrate, a reference electrode printed on the substrate, and a golden finger printed on the plastic substrate. The golden finger is for electrically coupling with the external world and for outward transmission of signals detected at the working electrode and the reference electrode. The disclosed plastic potentiometric ion-selective sensor is replaceable.

### BACKGROUND OF THE INVENTION

1. Field of the Invention

The present invention is related to a sensor and fabrication thereof, and more particularly to a plastic potentiometric ion-selective sensor and fabrication thereof by integrating sputtering and/or printing processes and embedded system technology.

2. Description of the Prior Art

Ion sensitive field effect transistors (ISFETs) are micro sensing devices starting in the 70's and being quickly developed. For only 30 years till now, there are more than 600 research papers and 150 other related papers, such as enzyme field effect transistors (EnFETs) and immuno field effect transistors (IMFETs) (P. Bergveld, “Thirty years of ISFETOLOGY: What happened in the past 30 years and what may happen in the next 30 years”, Sensors and Actuators B, Vol. 88, pp. 1-20, 2003.). In addition, ion sensitive field effect transistors can be used to measure pH values and ion concentrations, such as Na⁺, K⁺, Cl⁻, NH₄⁺, Ca²⁺, instead of fragile glass electrodes (Miao Yuqing, Guan Jianguo, and Chen Jianrong, “Ion sensitive field effect transducer-based biosensors”, Biotechnology Advances, Vol. 21, pp. 527-534, 2003.). The idea was first introduced by P. Bergveld. By using a metal oxide semiconductor field effect transistor (MOSFET) without a gate electrode, a device with a SiO₂ layer is placed in aqueous solution together with a reference electrode. The electric current passing the device changes with the hydrogen-ion concentration, whose response is similar to that of a glass electrode. Thus, it has the acid-base sensing characteristic (Chen Jian-pin, Lee Yang-li, Kao Hung, “Ion sensitive field effect transistors and applications thereof”, Analytical Chemistry, Vol. 23, No. 7, pp. 842-849, 1995; Wu Shih-hsiang, Yu Chun, Wang Kuei-hua, “Measurement by chemical sensors”, Sensor technology, No. 3, pp. 57-62, 1990).

Some ISFET sensing devices have been commercialized, such as ISFET pH meters made by Arrow Scientific, Deltatrak, and Metropolis. However, it has problems of stability and lifetime, for example drift phenomena and hysteresis effect. The present invention discloses another type of ISFETs, an extended gate field effect transistor (EGFET). The field effect transistor (FET) is isolated from the chemical measurement environment. The chemical sensing film is deposited on one end of the signal wire extended from the area of the gate electrode. The portions of the electric effect and the chemical effect are packaged separately. Therefore, compared to conventional ISFETs, EGFETs are easy in packaging and storage and have better stability (Liao Han-chou, “Novel calibration and compensation technique of circuit for biosensors”, June, 2004, Department of electrical engineering, Chung Yuan Christian University, Master dissertation, pp. 11-29).

Recently, there are many researches in characteristics of the extended gate ion sensitive field effect transistors, such as device design (Li Te Yin, Jung Chuan Chou, Wen Yaw Chung, Tai Ping Sun, and Shen Kan Hsiung, “Separate structure extended gate H⁺-ion sensitive filed effect transistor on a glass substrate”, Sensors and Actuators B, Vol. 71, 106-111, 2000; Li Te Yin, Jung Chuan Chou, Wen Yaw Chung, Tai Ping Sun, and Shen Kan Hsiung, “Study of indium tin oxide thin film for separative extended gate ISFET”, Materials Chemistry and Physics, Vol. 70, pp. 12-16, 2001;Li Te Yin, Jung Chuan Chou, Wen Yaw Chung, Tai Ping Sun, Kuang Pin Hsiung, and Shen Kan Hsiung, “Study on glucose ENFET doped with MnO₂ powder”, Sensors and Actuators B, Vol. 76, pp. 187-192, 2001;Yin Li-Te, “Study of Biosensors Based on an Ion Sensitive Field Effect Transistor”, June, 2001, Department of biomedical engineering, Chung Yuan Christian University, Ph. D. dissertation, pp. 76-108.), characteristic analysis (Jia Yong-Long, “Study of the extended gate field effect transistor (EGFET) and signal processing IC using the CMOS technology”, June, 2001, Department of electrical engineering, Chung Yuan Christian University, Ph. D. dissertation, pp. 36-44; Chen Jia-Chi, “Study of the disposable urea sensor and the pre-amplifier”, June, 2002, Department of biomedical engineering, Chung Yuan Christian University, Master dissertation, pp. 51-80; Jia Chyi Chen, Jung Chuan Chou, Tai Ping Sun, and Shen Kan Hsiung, “Portable urea biosensor based on the extended-gate field effect transistor”, Sensors and Actuators B, Vol. 91, pp. 180-186, 2003; Chung We Pan, Jung Chuan Chou, I Kone Kao, Tai Ping Sun, and Shen Kan Hsiung, “Using polypyrrole as the contrast pH detector to fabricate a whole solid-state pH sensing device”, IEEE Sensors Journal, Vol. 3, pp. 164-170, 2003;Jui Fu Cheng, Jung Chuan Chou, Tai Ping Sun, and Shen Kan Hsiung, “Study on the chloride ion selective electrode based on the SnO₂/ITO glass”, Proceedings of The 2003 Electron Devices and Materials Symposium (EDMS), National Taiwan Ocean University, Keelung, Taiwan, R.O.C., pp. 557-560, 2003; Jui Fu Cheng, Jung Chuan Chou, Tai Ping Sun, and Shen Kan Hsiung, “Study on the chloride ion selective electrode based on the SnO₂/ITO glass and double-layer sensor structure”, Proceedings of The 10th International Meeting on Chemical Sensors, Tsukuba International Congress Center, Tsukuba, Japan, pp. 720-721, 2004.), characteristics of drift phenomena and hysteresis effect (Liao Han-chou, “Novel calibration and compensation technique of circuit for biosensors”, Master dissertation, Department of electrical engineering, Chung Yuan Christian University, pp. 11-29, June, 2004; Chu Neng Tsai, Jung Chuan Chou, Tai Ping Sun, and Shen Kan Hsiung, “Study on the hysteresis of the metal oxide pH electrode”, Proceedings of The 10th International Meeting on Chemical Sensors, Tsukuba International Congress Center, Tsukuba, Japan, pp. 586-587, 2004; Chu Neng Tsai, Jung Chuan Chou, Tai Ping Sun, and Shen Kan Hsiung, “Study on the sensing characteristics and hysteresis effect of the tin oxide pH electrode”, Sensors and Actuators B, Vol. 108, pp. 877-882, 2005.).

### SUMMARY OF THE INVENTION

Compared to the above described prior arts, the present invention provides a plastic ion-selective sensor by integrating sputtering and/or printing processes and embedded system technology. An acid-base sensing electrode with a tin dioxide/indium tin oxide/plastics separate structure together with embedded system technology is used to fabricate the plastic ion-selective sensor.

The plastic potentiometric ion-selective sensor according to the present invention immediately displays the measurement result on a liquid crystal display and saves in a compact flash card so as to have portable functionality. In addition, the plastic potentiometric ion-selective sensor has data communication functionality with a computer. Finally, the drift and hysteresis software calibration technique is applied. Thus, this method can increase ion detection accuracy and system reliability. The device can be applied in pH value measurement. If other polymer selection substance is used, other type of ions can also be detected and applicability is also increased. It can also increase accuracy, applicability, and industrial applications in clinics, bio-signals, and environmental detection. Because the fabrication method requires only simple equipments, is also low in cost, and can be massively produced, the plastic potentiometric ion-selective sensor according to the present invention has very high applicability in pH value measurement.

The present invention discloses a plastic potentiometric ion-selective sensor based on field-effect transistors which can be fabricated to form the miniaturized component via sputtering and/or printing process. A plastic potentiometric ion-selective sensor doesn't need an additional bias voltage to convert the signals. The disclosed plastic sensor comprises a plastic substrate, at least one working electrode on the plastic substrate, a reference electrode printed on the substrate, and a golden finger printed on the plastic substrate, wherein the golden finger is for electrically coupling with the external world and for outward transmission of the signals detected at the working electrode and the reference electrode. The disclosed plastic potentiometric ion-selective sensor is replaceable.

### BRIEF DESCRIPTION OF THE DRAWINGS

FIG. 1 is a schematic diagram of the plastic potentiometric ion-selective sensor to the first embodiment of the present invention;

FIG. 2 is a lateral diagram of the plastic potentiometric biosensor according to the example of first embodiment of the present invention;

FIG. 3 is a lateral diagram of the plastic potentiometric biosensor according to the another example of first embodiment of the present invention;

FIG. 4 is a schematic diagram of the plastic potentiometric ion-selective sensor to the second embodiment of the present invention; and

FIG. 5 is a flow chart of the method for manufacturing the plastic potentiometric ion-selective sensor on a plastic substrate according to the present invention.

### DESCRIPTION OF THE PREFERRED EMBODIMENTS

What is probed into the invention is a plastic potentiometric ion-selective sensor. Detail descriptions of the structure and elements will be provided in the following in order to make the invention thoroughly understood. Obviously, the application of the invention is not confined to specific details familiar to those who are skilled in the art. On the other hand, the common structures and elements that are known to everyone are not described in details to avoid unnecessary limits of the invention. Some embodiments of the present invention will now be described in greater detail in the following specification. However, it should be recognized that the present invention can be practiced in a wide range of other embodiments besides those explicitly described, that is, this invention can also be applied extensively to other embodiments, and the scope of the present invention is expressly not limited except as specified in the accompanying claims.

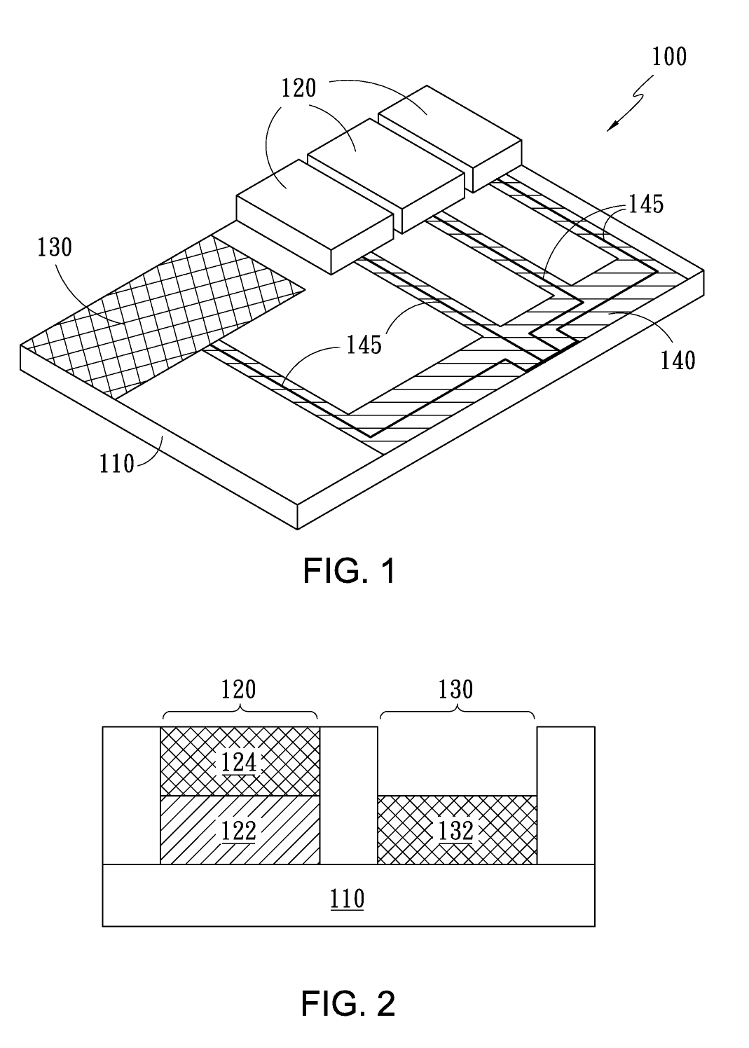

As shown in FIG. 1, a first embodiment of the present invention discloses a plastic potentiometric ion-selective sensor 100 for detecting pH value, comprising a plastic substrate 110, at least one working electrode 120 on the plastic substrate 110, a reference electrode 130 printed on the plastic substrate 110, and a golden finger 140 printed on the plastic substrate, and the golden finger is electrically coupled with the external world, to a device external to the plastic ion-selective sensor 100, and for outward transmission of a detection signal. The golden finger, which comprises a plurality of connecting wires 145, is respectively connected to the working electrode and reference electrode for transmitting the signal detected at the working electrodes 120 and the reference electrode 130. The material of the above-mentioned plastic substrate 110 comprises one selected from the group consisiting of the following: polyethylene terephthalate (PET), polycarbonates (PC), polyethylene naphthalate (PEN), polytetrafluoroethylene (PTFE), polyethersulfone (PES), polyetherimide (PEI), polyimide (PI), Metallocene based Cyclic Olefin Copolymer (mCOC), acrylonitrile-butadiene-styrene, polyethylene, acrylates, polymethyl methacrylate, polypropylene, polystyrene, polyvinyl chloride, epoxy resin, Acrylonitrile butadiene styrene (ABS), and their copolymer or heteropolymer.

As shown in FIG. 2, in this embodiment of the present invention, the above-mentioned working electrode 120, comprising a first conducting layer 122 formed on the plastic substrate 110, and a first sensing layer 124 formed on the conducting layer 122. Optionally, an ion-selective layer can be formed on the sensing layer 124. The ion-selective layer gives the plastic sensor 100 ability to detect many kinds of ions, such as sodium, calcium, potassium, chloride, and hydroxide. Therefore, the plastic sensor 100 can be applied not only in pH value measurement, but also in other ion concentration measurement. In some cases, the first sensing layer 124 can be skipped, and the ion-selective layer can be directly formed on the first conducting layer 122. The above-mentioned first conducting layer 122 possesses a low impedance so as to enhance the transmission efficiency of the detection signal, and the first conducting layer 122 comprises one selected from the group consisting of the following: gold, copper, carbon, silver, aurum, silver chloride, Indium tin oxides (ITO). The above-mentioned first sensing layer 124 comprises one selected from the group consisting of the following: tin dioxide, titanium dioxide, and titanium nitride.

In this embodiment of the present invention, the reference electrode 130 comprises a second sensing layer 132 formed on the plastic substrate 110. The second sensing layer 132 comprises one selected from the group consisting of the following: copper, carbon, silver, aurum, silver chloride, Indium tin oxides (ITO), and platinum.

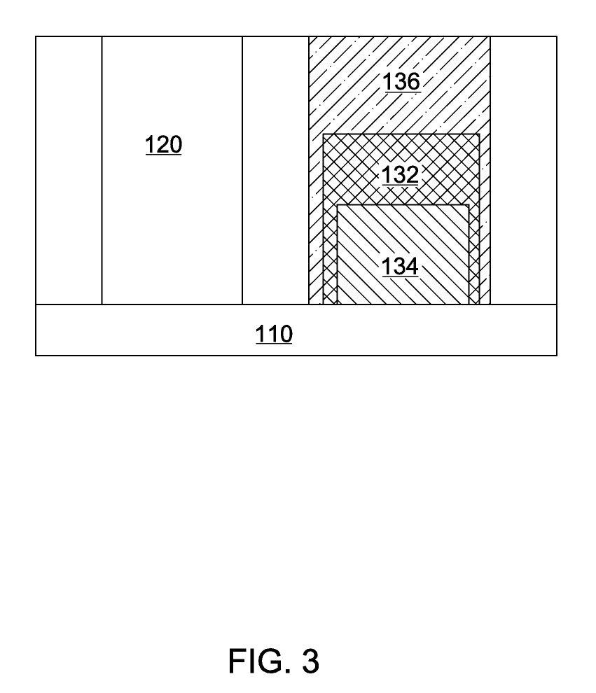

According to FIG. 3, one example of this embodiment is shown the reference electrode 130 comprises a second conducting layer 134 formed between the second sensing layer 132 and the plastic substrate 110. The second sensing layer 132 is overlaid by a quantity of an electrolyte, which may be a polymer or gel (layer 136) having a salt dispersed therein.

In some cases, the second sensing layer 132 can be skipped, and the polymer or gel layer 136 can be directly formed on the second conducting layer 134. The second conducting layer 134 comprises one selected from the group consisting of the following: gold, copper, carbon, silver, aurum, silver chloride, Indium tin oxides (ITO). The second sensing layer 132 comprises one selected from the group consisting of the following: copper, carbon, silver, aurum, silver chloride, Indium tin oxides (ITO), and platinum.

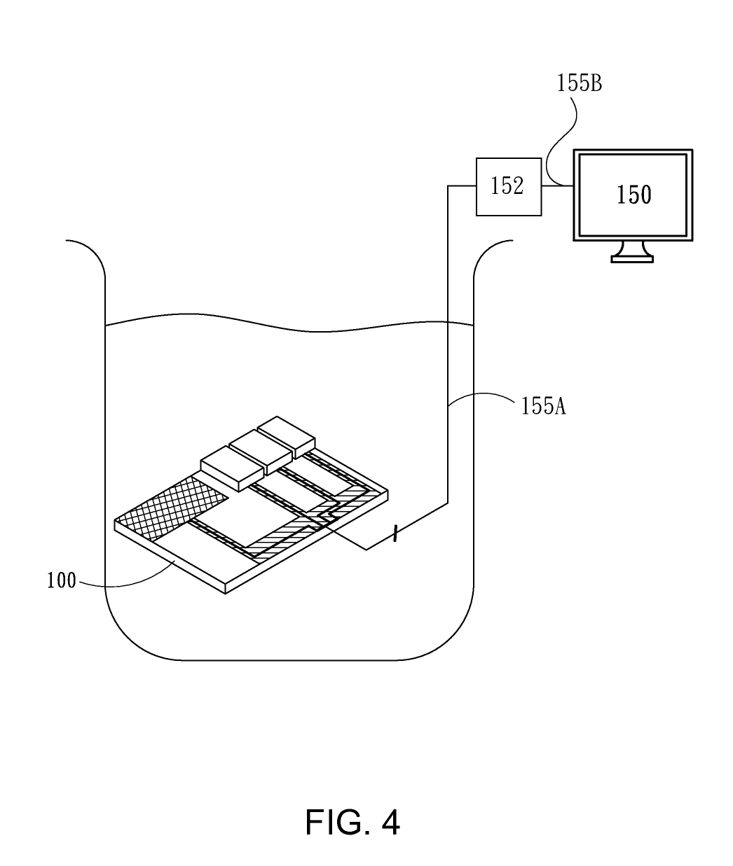

As shown in FIG. 4, a second embodiment of the present invention discloses a plastic potentiometric ion-selective sensor. The plastic potentiometric ion-selective sensor 100 is placed in an unknown solution. Software calibration is carried out to improve the problems of hysteresis effect and drift phenomena in the sensor unit. Following that, the two-point (pH4, pH7) calibration procedure is performed to eliminate the error so as to provide more accurate sensing signal. Finally, the pH value measurement result is calculated by a signal processing unit 152, such as signal-reading circuit or electric meter, and then displayed on a computer 150, a monitor, a liquid crystal display (LCD) for example, immediately and saved in a memory card, such as a compact flash card (CF card). The above-mentioned signal processing unit 152 can be directly printed on the plastic substrate 110 of the plastic potentiometric ion-selective sensor 100 for further lowering the fabrication cost. In a readout procedure from a CF card, data can be read to a computer via a card reader. In addition, the plastic sensor device according to the present invention can transmit the detected signals to a personal computer or a laptop computer via a wire or wireless transmission interface 155A and 155B, such as universal serial bus (USB) and universal asynchronous receiver/transmitter (UART) interfaces, so as to enhance the flexibility of the system. By the above described method, the pH value of the unknown solution is obtained quickly and accurately.

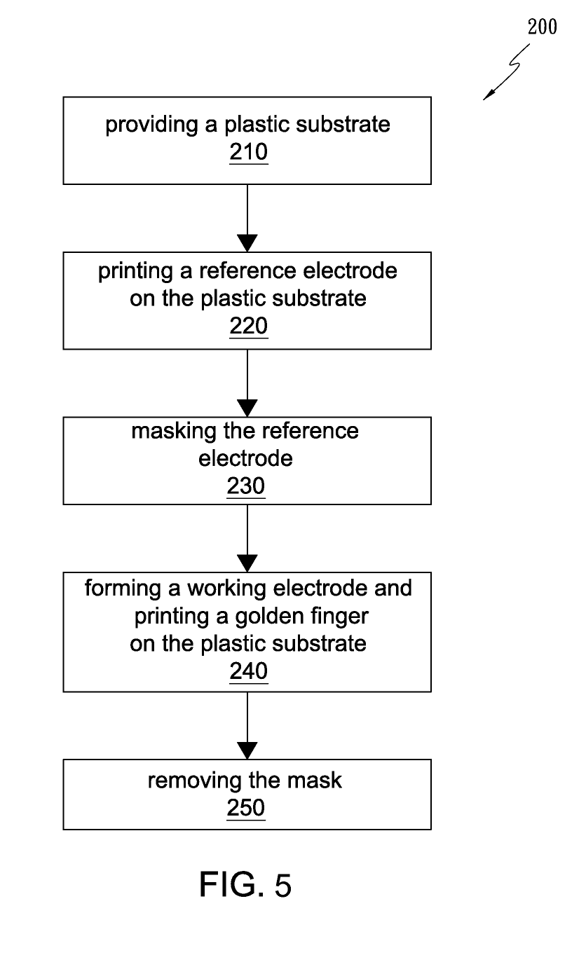

As shown in FIG. 5, the present invention discloses a method of manufacturing a plastic potentiometric ion-selective sensor. The flow chart 200 comprises five major steps. The first step 210 is providing the plastic substrate (the material of the plastic substrate is aforementioned), and the second step 220 is printing the reference electrode on the plastic substrate, and the third step 230 is masking the reference electrode as to conceal the reference electrode from the later steps, and the fourth step 240 is forming the working electrode on the plastic substrate and printing the golden finger on the plastic substrate, wherein the golden finger is for electrically coupling with the external world and for outward transmission of the signal detected at the working electrode or at the reference electrode, and the fifth step 250 is removing the mask. The potentiometric ion-selective sensor of the present invention is therefore manufactured. Another method of manufacturing a potentiometric ion-selective sensor, the reference electrode and working electrode can be printed on different plastic substrates independently and then combined the different substrates together.

One example of this embodiment is shown that a working electrode can be formed on the plastic substrate by a RF (radio frequency) sputtering method or by a printing method. Another example of this embodiment is shown that the fourth step 240 of forming the working electrode on the plastic substrate, further comprising: forming a first conducting layer on said plastic substrate; and forming a first sensing layer on the first conducting layer. The first conducting layer possesses a low impedance so as to enhance the transmission efficiency of the detection signal, and the first conducting layer comprises one selected from the group consisting of the following: golden, copper, carbon, silver, aurum, silver chloride, Indium tin oxides (ITO). The first sensing layer comprises one selected from the group consisting of the following: tin dioxide, titanium dioxide, and titanium nitride.

Other example of this embodiment is shown that the second step 220 of printing the reference electrode on the plastic substrate, further comprising: forming a second sensing layer on said plastic substrate. The second sensing layer comprises one selected from the group consisting of the following: copper, carbon, silver, aurum, silver chloride, platinum, and Indium tin oxides (ITO).

### EXAMPLE

According to the foregoing description, the working electrode, the reference electrode, and the golden finger printed on the plastic substrate are made by bonding a layer of copper over the entire substrate then removing unwanted copper after applying a temporary mask (eg. by etching), leaving only the desired copper traces. A few printing methods are used by adding traces to the bare substrate (or a substrate with a very thin layer of copper) usually by a complex process of multiple electroplating steps.

There are three common “subtractive” methods (methods that remove copper) used for the printed methods: (1) Silk screen printing uses etch-resistant inks to protect the copper foil. Subsequent etching removes the unwanted copper. Alternatively, the ink may be conductive, printed on a blank (non-conductive) board. (2) Photoengraving uses a photomask and chemical etching to remove the copper foil from the substrate. The photomask is usually prepared with a photoplotter from data produced by a technician, or computer-aided manufacturing software. Laser-printed transparencies are typically employed for phototools; however, direct laser imaging techniques are being employed to replace phototools for high-resolution requirements. (3) Milling uses a two or three-axis mechanical milling system to millaway the copper foil from the substrate.

“Additive” methods also exist. The most common is the “semi-additive” process. In this version, the unpatterned board has a thin layer of copper already on it. A reverse mask is then applied. (Unlike a subtractive process mask, this mask exposes those parts of the substrate that will eventually become the traces.) Additional copper is then plated onto the board in the unmasked areas; copper may be plated to any desired weight. Tin-lead or other surface platings are then applied. The mask is stripped away and a brief etching step removes the now-exposed original copper laminate from the board, isolating the individual traces.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A plastic potentiometric ion-selective sensor, comprising:
a plastic substrate;
at least one working electrode formed on said plastic substrate;
a reference electrode printed on said plastic substrate; and
a golden finger printed on said plastic substrate, wherein said golden finger is for electrically coupling with the external world and for outward transmission of a detection signal.

2. The plastic potentiometric ion-selective sensor according to claim 1, wherein said plastic substrate comprises one selected from the group consisiting of the following: polyethylene terephthalate (PET), polycarbonates (PC), polyethylene naphthalate (PEN), polytetrafluoroethylene (PTFE), polyethersulfone (PES), polyetherimide (PEI), polyimide (PI), Metallocene based Cyclic Olefin Copolymer (mCOC), acrylonitrile-butadiene-styrene, polyethylene, acrylates, polymethyl methacrylate, polypropylene, polystyrene, polyvinyl chloride, epoxy resin, Acrylonitrile butadiene styrene (ABS), and their copolymer or heteropolymer.

3. The plastic potentiometric ion-selective sensor according to claim 1, wherein said working electrode, comprising:
a first conducting layer formed on said plastic substrate; and
a first sensing layer formed on said first conducting layer.

4. The plastic potentiometric ion-selective sensor according to claim 3, wherein said first conducting layer possesses a low impedance so as to enhance the transmission efficiency of said detection signal, and said first conducting layer comprises one selected from the group consisting of the following: copper, carbon, silver, aurum, silver chloride, Indium tin oxides (ITO), and gold.

5. The plastic potentiometric ion-selective sensor according to claim 3, wherein said first sensing layer comprises one selected from the group consisting of the following: tin dioxide, titanium dioxide, and titanium nitride.

6. The plastic potentiometric ion-selective sensor according to claim 3, wherein said working electrode further comprising:
an ion-selective layer formed on top of said first sensing layer or said first sensing layer is replaced with said ion-selective layer.

7. The plastic potentiometric ion-selective sensor according to claim 1, wherein said reference electrode, comprising:
a second sensing layer formed on said plastic substrate, wherein said second sensing layer is selectively contact or non-contact with said plastic substrate.

8. The plastic potentiometric ion-selective sensor according to claim 7, wherein said second sensing layer comprises one selected from the group consisting of the following: copper, carbon, silver, aurum, silver chloride, Indium tin oxides (ITO), and platinum.

9. The plastic potentiometric ion-selective sensor according to claim 7, wherein said reference electrode further comprising:
a second conducting layer formed between said second sensing layer and said plastic substrate.

10. The plastic potentiometric ion-selective sensor according to claim 9, wherein said reference electrode further comprising:
a polymer or gel layer formed on top of said second sensing layer or said second sensing layer is replaced with said polymer or gel layer.

11. The plastic potentiometric ion-selective sensor according to claim 1, wherein said golden finger comprises a plurality of connecting wires respectively connected to said working electrode and said reference electrode, said detection signal is respectively generated from said working electrode and said reference electrode via said plurality of connecting wires.

12. The plastic potentiometric ion-selective sensor according to claim 1, further comprising a signal processing unit printed on said plastic substrate, wherein said signal processing unit is for receiving and processing said detection signal.

13. A method of manufacturing a plastic potentiometric ion-selective sensor, comprising:
providing a plastic substrate;
printing a reference electrode on said plastic substrate;
masking said reference electrode as to conceal said reference electrode from later process;
forming a working electrode on said plastic substrate and printing a golden finger on said plastic substrate, wherein said golden finger is for electrically coupling with the external world and for outward transmission of a detection signal; and
removing the mask.

14. The method of manufacturing the plastic potentiometric ion-selective sensor according to claim 13, wherein said plastic substrate comprises one selected from the group consisting of the following: polyethylene terephthalate (PET), polycarbonates (PC), polyethylene naphthalate (PEN), polytetrafluoroethylene (PTFE), polyethersulfone (PES), polyetherimide (PEI), polyimide (PI), Metallocene based Cyclic Olefin Copolymer (mCOC), acrylonitrile-butadiene-styrene, polyethylene, acrylates, polymethyl methacrylate, polypropylene, polystyrene, polyvinyl chloride, epoxy resin, Acrylonitrile butadiene styrene (ABS), and their copolymer or heteropolymer.

15. The method of manufacturing the plastic potentiometric ion-selective sensor according to claim 13, wherein said working electrode is formed on said plastic substrate by a printing method.

16. The method of manufacturing the plastic potentiometric ion-selective sensor according to claim 13, wherein said working electrode is formed on said plastic substrate by a RF (radio frequency) sputtering method.

17. The method of manufacturing the plastic potentiometric ion-selective sensor according to claim 13, wherein the step of forming said working electrode on said plastic substrate, further comprising:
forming a first conducting layer on said plastic substrate; and
forming a first sensing layer on said first conducting layer.

18. The method of manufacturing the plastic potentiometric ion-selective sensor according to claim 17, wherein said first conducting layer possesses a low impedance so as to enhance the transmission efficiency of said detection signal, and said first conducting layer comprises one selected from the group consisting of the following: copper, carbon, silver, aurum, silver chloride, Indium tin oxides (ITO), and gold.

19. The method of manufacturing the plastic potentiometric ion-selective sensor according to claim 17, wherein said first sensing layer comprises one selected from the group consisting of the following: tin dioxide, titanium dioxide, and titanium nitride.

20. The method of manufacturing the plastic potentiometric ion-selective sensor according to claim 13, wherein the step of printing said reference electrode on said plastic substrate, further comprising:
forming a second sensing layer on said plastic substrate, wherein said second sensing layer comprises one selected from the group consisting of the following: copper, carbon, silver, aurum, silver chloride, Indium tin oxides (ITO), and platinum.

21. The method of manufacturing the plastic potentiometric ion-selective sensor according to claim 13, wherein said golden finger comprises a plurality of connecting wires respectively connected to said working electrode and said reference electrode, said detection signal is respectively generated from said working electrode and said reference electrode via said plurality of connecting wires.

22. The method of manufacturing the plastic potentiometric ion-selective sensor according to claim 13, wherein said printing is selected from one of the following methods: subtractive methods, silk screen printing, photoengraving, milling, and additive methods.

23. The method of manufacturing the plastic potentiometric ion-selective sensor according to claim 13, before removing the mask, further comprising printing a signal processing unit on said plastic substrate, wherein said signal processing unit is for receiving and processing said detection signal.
